(19) United States
(12) Patent Application Publication
(10) Pub. No.: US 2012/0286416 A1
(43) Pub. Date: Nov. 15, 2012

(54) SEMICONDUCTOR CHIP PACKAGE ASSEMBLY AND METHOD FOR MAKING SAME

(75) Inventors: Hiroaki Sato, Yokohama (JP); Yukio Hashimoto, Hitachinaka (JP); Yoshikuni Nakadaira, Hodogaya-Ku (JP); Norihito Masuda, Yokohama (JP); Belgacem Haba, Saratoga, CA (US); Ilyas Mohammed, Santa Clara, CA (US); Philip Damberg, Cupertino, CA (US)

(73) Assignee: TESSERA RESEARCH LLC, San Jose, CA (US)

(21) Appl. No.: 13/105,325

(22) Filed: May 11, 2011

(51) Int. Cl. H01L 23/498; H01L 21/60

(52) U.S. Cl. 257/737; 438/124; 257/E21.499; 257/E23.068

(57) ABSTRACT

A microelectronic assembly may include a microelectronic element having a plurality of element contacts at a face thereof, and a compliant dielectric element having a Young's modulus of less than about two gigapascal (GPa) and substrate contacts at a first surface joined to the element contacts. The substrate contacts may be electrically connected with terminals at a second surface of the compliant dielectric element that opposes the first surface, through conductive vias in the compliant dielectric element. A rigid underfill may be between the face of the microelectronic element and the first surface of the compliant dielectric element. The terminals may be usable for bonding the microelectronic assembly to corresponding contacts of a component external to the microelectronic assembly.

### BACKGROUND

The subject matter shown and described in the present application relates to assemblies in which semiconductor chips are packaged and to methods and components useful in making such assemblies.

Modern electronic devices utilize semiconductor chips, commonly referred to as “integrated circuits” which incorporate numerous electronic elements, such as transistors or other active circuit elements. These chips are mounted on substrates which physically support the chips and electrically interconnect each chip with other elements of the circuit. For example, the chip may be mounted in a face-down arrangement, so that a front surface of the chip having contacts thereon confronts a top surface of the substrate and a rear surface of the chip faces upwardly, away from the top surface of the substrate.

The substrate may be a part of a discrete chip package or microelectronic assembly used to hold a single chip and equipped with terminals for interconnection to external circuit elements. Such substrates may be secured to an external circuit board or chassis. Alternatively, in a so-called “hybrid circuit” one or more chips are mounted directly to a substrate forming a circuit panel arranged to interconnect the chips and the other circuit elements mounted to the substrate. In either case, the chip must be securely held on the substrate and must be provided with reliable electrical interconnection to the substrate.

In a microelectronic assembly, structures electrically interconnecting a chip to a substrate ordinarily are subject to substantial strain caused by thermal excursions or cycling between low and high temperatures as temperatures within the device change, such as may occur during fabrication, operation or testing of the device. For example, during operation, the electrical power dissipated within the chip tends to heat the chip and substrate, so that the temperatures of the chip and substrate rise each time the device is turned on and fall each time the device is turned off. As the chip and the substrate ordinarily are formed from different materials having different coefficients of thermal expansion, the chip and substrate ordinarily expand and contract by different amounts. This may cause electrical contacts on the chip to move relative to electrical contacts, such as pads, on the substrate and to terminals on a rear surface of the substrate that connect the substrate to another element, such as another microelectronic element, as the temperature of the chip and the substrate changes. This relative movement can deform electrical interconnections between the chip and substrate, and the another microelectronic element and substrate, and place them under mechanical stress. These stresses are applied repeatedly with repeated operation of the device, and can cause breakage of the electrical interconnections, which in turn reduces reliability performance of the device. Thermal cycling stresses may occur even where the chip and substrate are formed from like materials having similar coefficients of thermal expansion, because the temperature of the chip may increase more rapidly than the temperature of the substrate when power is first applied to the chip.

Improvements can be made to structures that provide for electrical interconnection of a chip to a substrate of a microelectronic assembly and the processes used to fabricate such structures.

### SUMMARY

In accordance with an aspect of the invention, a microelectronic assembly may include a microelectronic element having a plurality of element contacts at a face thereof, and a compliant dielectric element having a Young's modulus of less than about two gigapascal (GPa). The compliant dielectric element may have a first surface facing the face of the microelectronic element, a second surface opposed thereto, a plurality of substrate contacts at the first surface joined to the element contacts, first traces extending along the first surface away from the substrate contacts, a plurality of terminals at the second surface, and a plurality of first conductive vias. The substrate contacts may be electrically connected with the terminals through the first conductive vias. The assembly further may include a rigid underfill between the face of the microelectronic element and the first surface of the compliant dielectric element. The terminals may be usable for bonding the microelectronic assembly to corresponding contacts of a component external to the microelectronic assembly.

In accordance with another aspect of the invention, a microelectronic assembly may include a microelectronic element having a plurality of element contacts at a face thereof, and a compliant dielectric element having a Young's modulus of less than about two GPa. The compliant dielectric element may have a first surface facing the face of the microelectronic element, a second surface opposed thereto, a plurality of substrate contacts at the first surface joined to the element contacts, traces extending along the first surface away from the substrate contacts, a plurality of terminals at the second surface, and a plurality of conductive vias. The substrate contacts may be electrically connected with the terminals through the conductive vias. The assembly further may include a rigid underfill between the face of the microelectronic element and the first surface of the compliant dielectric element. The terminals may be electrically connected with the conductive vias and usable for bonding the microelectronic assembly to corresponding contacts of a component external to the microelectronic assembly such that the terminals are movable with respect to the substrate contacts.

In accordance with a further aspect of the invention, a method of fabricating a microelectronic assembly may include joining element contacts at a face of a microelectronic element with a plurality of substrate contacts at a first surface of a compliant dielectric element. The compliant dielectric element may have a Young's modulus of less than about two GPa and a second surface opposed to the first surface, traces extending along the first surface away from the substrate contacts, a conductive structure at the second surface and a plurality of conductive vias. The method may include forming a rigid underfill between the face of the microelectronic element and the first surface of the compliant dielectric element. Further, the method may include patterning the conductive structure after the joining step to form terminals at the second surface of the compliant dielectric element, where the substrate contacts are electrically connected with the terminals through the conductive vias and the terminals are usable to electrically connect the microelectronic assembly to a component external to the microelectronic assembly.

### BRIEF DESCRIPTION OF THE DRAWINGS

FIGS. 1-5 are diagrammatic sectional views illustrating stages in a method of fabricating a substrate, in accordance with one embodiment of the invention.

FIG. 6 is a diagrammatic sectional view of a microelectronic assembly formed using the substrate of the method of FIGS. 1-5, in accordance with one embodiment of the invention.

FIG. 7 is a diagrammatic sectional view of a microelectronic assembly, in accordance with another embodiment of the invention.

FIG. 8 is a diagrammatic sectional view of a microelectronic assembly, in accordance with yet another embodiment of the invention.

FIG. 9 is a diagrammatic sectional view of a microelectronic assembly, in accordance with yet another embodiment of the invention.

FIG. 10 is a diagrammatic sectional view of a microelectronic assembly, in accordance with yet another embodiment of the invention.

FIG. 11 is a diagrammatic sectional view of a microelectronic assembly, in accordance with yet another embodiment of the invention.

FIG. 12 is a schematic depiction of a system according to one embodiment of the invention.

FIGS. 13(a)-13(h) are diagrammatic sectional views illustrating stages in a method of fabricating a microelectronic assembly, in accordance with one embodiment of the invention.

FIGS. 14(a)-14(c) are diagrammatic sectional views illustrating stages in a method of fabricating a substrate, in accordance with one embodiment of the invention.

### DETAILED DESCRIPTION

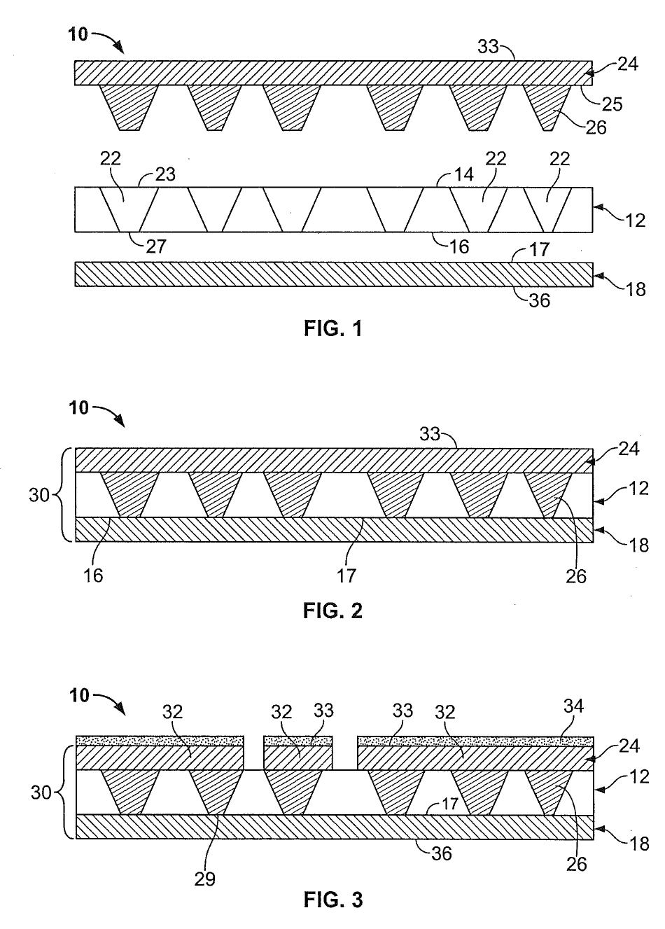

A substrate 10 fabricated, in accordance with an embodiment of the present invention, for mounting a microelectronic element, such as a semiconductor chip, thereto may include a compliant dielectric element 12 having an inside surface 14 facing upwardly and an outer surface 16 facing downwardly, as shown in FIG. 1. As will be seen in the various embodiments provided herein, the compliant dielectric element 12 may include one or more layers of compliant dielectric material and have conductive vias extending through a thickness of the one or more dielectric layers.

As used in this disclosure, terms such as “upwardly,” “downwardly,” “vertically” and “horizontally” should be understood as referring to the frame of reference of the element specified and need not conform to the normal gravitational frame of reference. Also, for ease of reference, directions are stated in this disclosure with reference to a “top” or “front” surface of a substrate, such as a top surface 33 of a conductive layer 24 of the substrate 10 as shown in FIG. 2. Generally, directions referred to as “upward” or “rising from” shall refer to the direction orthogonal and away from the front surface of the substrate. Directions referred to as “downward” shall refer to the directions orthogonal to the front surface of the substrate and opposite the upward direction. A “vertical” direction shall refer to a direction orthogonal to a front surface of the substrate. The term “above” a reference point shall refer to a point upward of the reference point, and the term “below” a reference point shall refer to a point downward of the reference point. The “top” of any individual element shall refer to the point or points of that element which extend furthest in the upward direction, and the term “bottom” of any element shall refer to the point or points of that element which extend furthest in the downward direction.

The compliant dielectric element 12 may have a Young's modulus of less than about 2 GPa, and be a solid, uniform layer including one or more of silicone, a low modulus epoxy, a TEFLON based material, a foam type material, a liquid-crystal polymer, a thermoset polymer, a fluoropolymer, a thermoplastic polymer, polyimide, polytetrafluoroethylene (PTFE), perfluoroalkoxy (PFA), fluorinated ethylene propylene (FEP) and polyfluoroethylene (PTFE) or like materials. In a particular embodiment, the compliant dielectric layer may have elastic properties comparable to those of soft rubber and have about 20 to 70 Shore A durometer hardness. The compliant dielectric layer may have a thickness between the surfaces 14 and 16 of about 15-20 microns.

In addition, the compliant dielectric element 12 has holes 22 formed therein extending between the inside surface 14 and the outside surface 16. The holes 22 may be substantially cone-shaped or cylindrically-shaped having substantially circularly-shaped top ends 23 at the surface 14 and substantially circularly-shaped bottom ends 27 at the surface 16. The holes 22 may have an average diameter or width of about 25-50 microns. The difference between the diameter or width of the top ends 23 of the holes 22 and the diameter or width of the bottom ends 27 may be about 5-10 microns. In some examples, the width of the bottom end of a hole can be smaller than the width at the top end; in another example, the bottom end width of the hole can be the same as the top end width.

The substrate 10 also may include a planar conductive layer 18 formed from an etchable conductive material, which is desirably a metal, such as copper, a copper-based alloy, aluminum, nickel and gold. The conductive layer 18 most typically is about 12-300 μm thick between top surface 17 and bottom surface 36.

The substrate 10 further may include an inner conductive layer 24 with projections 26 extending from a bottom surface 25 of the layer 24. The projections 26 are disposed in a pattern corresponding to the pattern of the holes 22 in the compliant dielectric element 12. The layer 24 may be formed from a metal, such as used to from the layer 18, and most typically is about 5-20 μm thick between the top and bottom surfaces. In one embodiment, the layer 24 with the projections 26 may be a unitary structure, with the projections formed integrally with the layer 24.

In one stage of fabrication of the substrate, the conductive layers 18 and 24 may be laminated, individually or simultaneously, to the compliant dielectric element 12 to form an in-process structure 30, as shown in FIG. 2. In the structure 30, the conductive layers 24 and 18 are electrically connected with each other by the projections 26. The projections 26 act as conductive vias extending through the holes 22 of the compliant dielectric element 12 electrically connecting the conductive layers 18 and 24 with each other. The conductive vias 26 desirably fill the entirety of the holes 22 so as to have the same structure as the holes.

In one embodiment, a lamination process may be performed so that the conductive vias 26 extend from the layer 24, through the holes 22 and abut the inner surface 17 of the conductive layer 18. To assure abutting contact, the height of the projections 26 prior to lamination may be slightly greater than the thickness of the element 12, and the element 12 and layer 18 are squeezed together so that the projections 26 are slightly flattened by engagement with the layer 18.

In a further embodiment, the abutting surfaces of the projections 26 and the layer 18 are bonded to each other. The bonding of the projections to the layer 18 may be performed, for example, as disclosed in U.S. Pat. No. 7,495,179, incorporated by reference herein.

In addition, in the in-process structure 30, the inner conductive layer 24 adheres to the upper surface 14, and the conductive layer 18 adheres to the lower surface 16, of the compliant dielectric element 12, based on plating of the layers 18 and 24 on the element 12. Alternatively, a compliant dielectric layer from which the compliant dielectric element 12 is formed may be provided in a partially-cured state and further cured in contact with the layer 24 and/or the layer 18 during the lamination process. Although the individual layers are depicted separately in FIG. 1, a compliant dielectric layer may be carried into the lamination process on the layer 24 or the layer 18. For example, the compliant dielectric layer may be provided with the holes 22, such as by ablating, punching or etching a continuous dielectric layer to form the holes, and then laminated to the conductive layer 18 and/or the conductive layer 24. Alternatively, the compliant dielectric element 12 may be formed on either of the conductive layers 18, 24, such as by coating the conductive layer with a liquid precursor and then curing the precursor to form the dielectric element. In an embodiment where the compliant dielectric element includes photosensitive material, such as a photosensitive material of the type commonly used as a solder mask on electronic components, the holes 22 may be formed by photolithographically patterning the dielectric element. In a further embodiment, a completely or partially cured solid compliant dielectric layer without pre-formed holes may be forcibly engaged with an inner conductive layer bearing projections so that the projections penetrate through the compliant dielectric layer. The projections may be formed with sharp points or sharp edges to facilitate this process.

In a further stage of the process, the inner conductive layer 24 of the in-process structure 30 may be treated by patterning a photoresist or other etch-resistant material on the surface 25 of the layer 24 by conventional photolithographic patterning procedures, and then exposing exposed portions of the surface 25 of the layer 24 to an etchant which attacks the material of the layer 18. The etchant exposure is continued for a time sufficient to remove those portions of the layer 24 not covered by the photoresist. After removal of the portions of the layer 24, portions 32 of the layer 24 remain, as shown in FIG. 3. The etch-resistant material is removed from the portions 32, following the etching process. The remaining portions 32 of the inner conductive layer 24 may include contacts for electrical connection of the substrate 10 to a semiconductor chip, and traces extending along the surface 14 from such contacts to electrically connect the contacts with other conductive elements within or attached to the substrate as described in detail below.

In a further embodiment, referring to FIG. 3, the substrate 10 may optionally include a protective layer 34 formed on the upper surfaces 33 of the conductive portions 32. The protective layer 34 may include a corrosion-resistant or oxidation-resistant metal, such as nickel or gold, or be formed from organic solderability preservative (“OSP”) or a flux material. In one embodiment, the etch-resistant material used to form the portions 32 may also include a corrosion-resistant metal, such as nickel or gold, such that the material may be left in place as the layer 34 after formation of the portions 32.

In a further stage of the process, the conductive layer of the substrate 10 may be treated. In one embodiment, an etch-resistant material, such as a photoresist (not shown), may be applied on portions of outer surface 36 of the layer 18 that are not aligned with the conductive vias 26 exposed at the surface 16 of the compliant dielectric element. The etch-resistant material may be applied to and maintained on the surfaces of the layer 18 to remove portions thereof, using similar techniques as described above, to obtain remaining conductive portions 38 of the layer 18. Some of the conductive portions 38 may be electrically connected, and optionally in contact, with bottom surfaces 29 of the conductive vias 26.

As used in this disclosure, an electrically conductive feature can be considered “exposed at” a surface of a dielectric layer if the metallic feature is accessible to a contact or bonding material applied to such surface. Thus, a metallic feature which projects from the surface of the dielectric or which is flush with the surface of the dielectric is exposed at such surface; whereas a recessed conductive feature disposed in or aligned with a hole in the dielectric extending to the surface of the dielectric is also exposed at such surface.

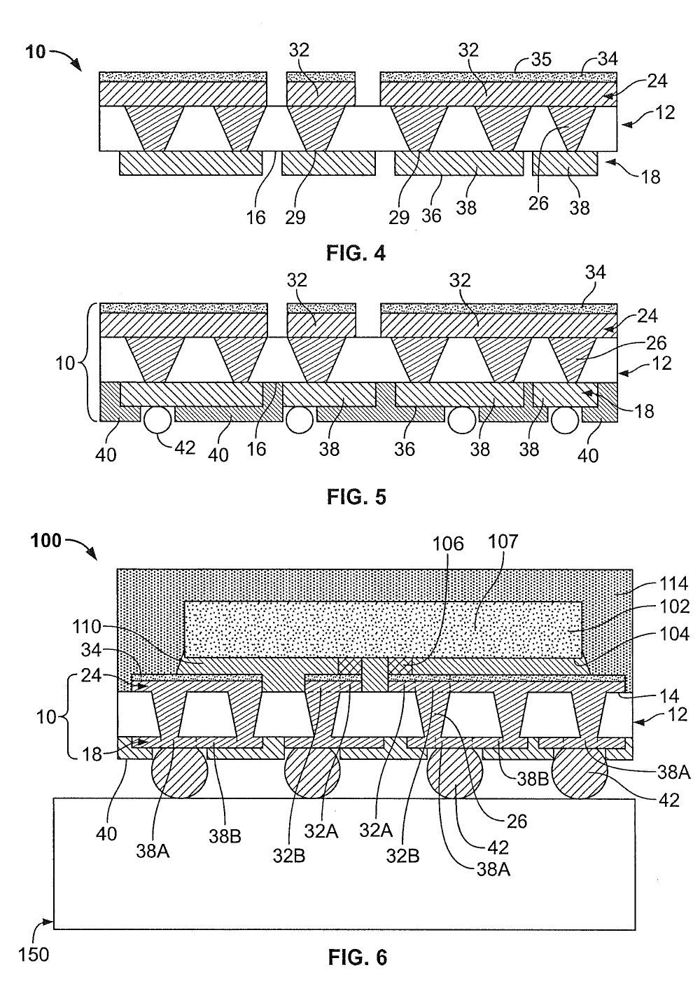

Referring to FIG. 4, conductive layers 18 and 24 extend along opposed surfaces of the compliant dielectric element 12, and the conductive vias 26 extending through the element 12 electrically connect the portions 38 of the conductive layer 18 with the portions 32 of the conductive layer 24. The portions 38 may constitute terminals that may be electrically connected with a microelectronic element, such as a semiconductor chip, which is external to the substrate 10. The portions 38 may be electrically connected through the conductive vias 26 with a microelectronic element electrically connected with the portions 32 of the conductive layer 24, as discussed in further detail below.

In one embodiment, referring to FIG. 5, after formation of the conductive portions 38, a solder resist layer 40 may be formed overlying the surface 16 of the compliant dielectric element 12. The layer 40 may be formed on uncovered portions of the outer surface 16 of the element 12 and patterned on exposed portions of outer surface 36 of the conductive portions 38. The solder resist layer 40 may be formed from a photoimageable or other material and have a thickness of about 10-25 microns.

Masses 42 of electrically conductive material, such as solder, may be formed on exposed portions of the surface 36 of the conductive portions 38, following formation of the solder resist layer 40. The masses 42 may be electrically interconnected with the conductive portions 32 through the conductive portions 38, which may include contacts that serve as the terminals of the substrate 10, and the conductive vias 26. The masses 42 may include a bond metal such as solder, which may or may not be lead-free, or such as tin or indium.

It is to be understood that the order of steps used to make the substrate 10 can be varied from that discussed above. For example, although the steps of treating the conductive layer 18 and the conductive layer 24 have been described sequentially above for ease of understanding, these steps may be performed in any order or simultaneously. For example, the conductive layers 18 and 24 may be etched simultaneously after application of photoresists. Also, the conductive layer 24 may be in the form of individual conductive features, such as portions that may be contacts and traces, when initially united with the compliant dielectric layer. For example, the conductive portions may be formed by selective deposition on the compliant dielectric element before or after treatment of the conductive layer. If the inner conductive layer 24 is formed by deposition on the inner surface of the compliant dielectric element before treatment of the conductive layer 18, the projections 26 may be formed in the same deposition step.

In some embodiments, the conductive layers may be formed by sputtering or blanket metallization, and followed by surface patterning using photolithography. See U.S. Patent Publication No. 2008-0116544, filed Nov. 22, 2006, incorporated by reference herein. Alternatively, the conductive layer may be formed by electroless plating.

In a further variant, the projections 26 may be initially formed on the conductive layer 18 rather than on the inner conductive layer 24. In this case, the conductive layer 18 may be treated before or after application of the inner conductive layer. Also, the step of forming holes in the compliant dielectric element may be performed before or after the other steps of the process. Also, the various steps may be, and most preferably are, conducted while the compliant dielectric element is part of a larger sheet or tape. Individual substrate components as depicted in FIG. 5 can be obtained by severing such a sheet or tape. Most typically, however, the substrate components are left in the form of a sheet or tape until after semiconductor chips or other devices are mounted to the substrate components.

In a further embodiment, a compliant dielectric layer may be cast or molded around the projections 26, for example, by engaging the inner conductive layer 24, the projections 26 and the conductive layer 18 in a compression mold or injection mold, and injecting uncured compliant dielectric material around the projections so as to form the compliant dielectric element in place. Alternatively, a compliant dielectric layer may be applied as a flowable material that may flow to form a layer surrounding the projections under the influence of gravity or under the influence of centrifugal force applied in a centrifuge or similar device.

In one embodiment, the substrate may be formed with a layer of solder resist on the surface 14 of the compliant dielectric element 12.

A microelectronic assembly 100 (FIG. 6) made using the substrate 10 of FIG. 5 may incorporate a microelectronic element 102, such as a semiconductor chip, having a generally planar front face 104, a generally planar rear face 107 and contacts (not shown) exposed at the front face 104. The substrate 10 and the chip 102 may be assembled with the chip 102 mounted on the substrate 10 in a front-face-down orientation, with the front face 104 of the chip facing the top surface 33 of the conductive portions 32. The contacts on the chip 102 may be electrically connected to internal electronic components (not shown) of the chip 102.

In addition, the contacts on the surface 104 of the chip may be aligned and bonded with conductive material of the substrate, such as contacts 32A of the conductive portions 32, or a contact (not shown) on the optional layer 34, by masses 106 of electrically conductive material. The masses 106 may include a bond metal such as solder, which may or may not be lead-free, or such as tin or indium.

Traces 32B of the conductive portions 32 extend along the surface 14 of the compliant dielectric element 12 away from the contacts 32A and electrically connect the contacts 32A with the conductive vias 26, which extend downwardly from the traces 32B. The traces 32B may partially overlie and be in contact with the conductive vias 26, such that the traces 32B electrically connect the contacts 32A with the vias 26. The conductive portions 38, thus, are electrically connected with the contacts on the chip 102, by the conductive vias 26. The conductive portions may include contacts 38A and traces 38B extending from the contacts 38A. The contacts 38A and the traces 38B may be electrically connected with the vias 26. The contacts 38A serve as terminals that may provide for electrical connection of the vias 26, through the traces 38B, with contacts (not shown) of an external microelectronic element 150, through the solder masses 42 formed on the outer surface 36 of the contacts 38A.

In one embodiment, a microelectronic package may be formed by using the terminals 38A to bond the assembly 100 to corresponding contacts of the external microelectronic element 150, which may be a circuit panel included in electronic devices such as a smart phone, mobile phone, personal digital assistant (PDA) and the like, with bonding material, such as solder, between the terminals and the circuit panel that joins the assembly 100 with the circuit panel. In a further embodiment, the bonding material may be the solder masses 42 of the assembly 100. Alternatively, the solder masses 42 may be omitted from the assembly 100, and bonding material, such as solder, may be applied at the terminals 38A when the assembly 100 is joined to the external microelectronic element 150.

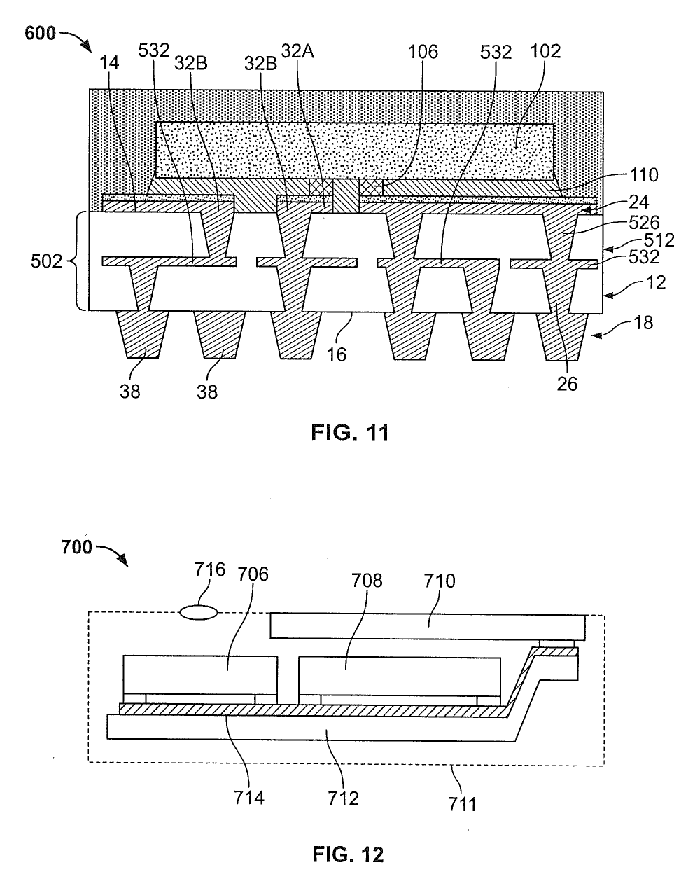

In one embodiment, in the assembly 100, a compliant dielectric element may include the compliant dielectric layer 12 having the terminals 38 at the surface 16, the substrate contacts 32A at the surface 14 and the traces 32B extending along the surface 14 away from the contacts 32A, and the conductive vias 26 extending therethrough and electrically connecting the substrate contacts with the terminals. In a further embodiment, the compliant dielectric element may be formed from a plurality of adjacent layers of compliant dielectric material with conductive traces in between the adjacent layers, as described in detail below in the text accompanying the description of FIGS. 10-11.

Referring to FIG. 6, the assembly 100 further may include a rigid underfill 110 between the surface 104 of the chip 102 and surface 14 of the compliant dielectric element 12 facing the chip. The rigid underfill 110 may be formed adhered to portions of the surface 14 of the element 12, exposed portions of the conductive portions 32 and exposed portions of the optional protective layer 34. In one embodiment, the rigid underfill 110 may overlie portions of the surface 14 of the element 12 adjacent to the chip 102. The rigid underfill 110 may have a Young's modulus of about 6 GPa or greater and include dielectric material.

In a further embodiment, a layer of encapsulant 114 may be provided covering portions of the substrate, and portions of the chip and the underfill, to protect the encapsulated components from the external environment. The encapsulant 114 may include dielectric material, and may or may not be molded, such as shown in FIG. 6.

In another embodiment, underfill and a layer of encapsulant may be made of the same material, such as a dielectric material, and applied at the same time, such as part of a molding process.

In accordance with the present invention, the structural and material characteristics of the substrate contacts, the terminals and the compliant dielectric element between the substrate contacts and the terminals may be adapted to permit displacement of the substrate contacts relative to the terminals of the substrate, and provide that the displacement appreciably relieves mechanical stresses, such as may be caused by differential thermal expansion or contraction, which would be present in electrical connections between the substrate contacts and a microelectronic element connected with the terminals absent such displacement. In particular, the structural and material characteristics of the substrate contacts, the compliant dielectric element and the terminals may be adapted to permit more movement of the terminals relative to the substrate contacts, in comparison to the amount of relative movement that would be permitted absent the combination of the compliant dielectric element between the substrate contacts and the terminals, the substrate contacts and the terminals adapted in accordance with the present invention, so as to appreciably reduce mechanical stresses in electrical connections between the associated contacts of the substrate with the chip attached thereto and part of the assembly and a chip attached at the terminals of the assembly.

As used in the claims with respect to contacts of a substrate joined to a microelectronic element in a microelectronic assembly, the term “movable” means that when the assembly is exposed to external loads, such as may occur as a result of thermal excursions during fabrication, testing or operation of the inventive assembly, the contacts are capable of being displaced relative to the terminals of the substrate by the external loads applied to the substrate contacts, based on the compliancy of the compliant dielectric element, to the extent that the displacement appreciably relieves mechanical stresses, such as those caused by differential thermal expansion which would be present in the electrical connections of the substrate at the surface facing the front facing microelectronic element and the surface at which the terminals are bonded to an external microelectronic element.

Referring to FIG. 6, in the completed assembly 100, the solder masses 42, which may be bonded to the contacts 38A that serve as terminals of the substrate 10, and the contacts 38A serving as the terminals, desirably can move or tilt slightly with respect to the contacts 32A of the inner conductive layer 24, based on the compliancy of the compliant dielectric element between the conductive layers 18 and 24. The compliant dielectric element can flex or otherwise deform to accommodate movement of the terminals 38A relative to the contacts 32A bonded to the chip, when the terminals 38A are attached to an external component, as may be caused, for example, by differential thermal expansion and contraction of the elements during operation, during manufacture as, for example, during a solder bonding process, or during testing.

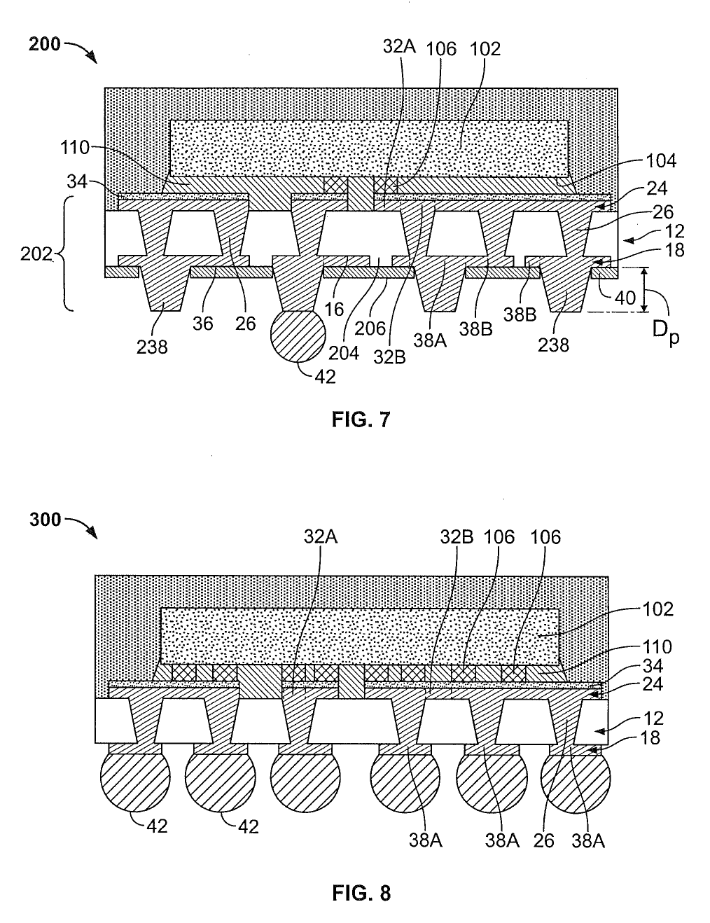

In a further embodiment, referring to FIG. 7, a microelectronic assembly 200 may include the chip 102 electrically connected with a substrate 202, which is fabricated and has features similar to the substrate 10. Like reference numerals are used in this embodiment, and also other embodiments discussed below, to designate the same or similar components as previously discussed. The substrate 202, which is connected to the chip 102 through the masses 106, includes the compliant dielectric element 12 laminated to and between the inner conductive layer 24 and the conductive layer 18, and the conductive vias 26 extending through the holes 22 of the element 12 and electrically connecting conductive portions of the layers 18 and 24 with each other. Further, the rigid underfill 110 is between the face 104 of the chip 102 and the side 45 of the substrate 202, similarly as in the assembly 100. In this embodiment, however, fabrication is performed to laminate the conductive layer 18 to the element 12, so that projections 204 of dielectric material of the compliant dielectric element 12 extend from the surface 16 downwardly through openings between the conductive portions 38 of the layer 18.

Also in this embodiment, the conductive layer 18 may include projections 238 of rigid conductive material extending downwardly from the surface 36 of the conductive portions 38. The projections 238 may serve as the terminals of the substrate that may electrically connect an external microelectronic element with the conductive vias 26 and the conductive portions 32. The projections 238 may be integral with the conductive portions 38 of the layer 18, or alternatively be part of another conductive layer laminated to the layer 18 at the outer surface 36. In addition, a solder resist layer 40 may overlie portions of traces 38B and a portion of the surface 16 of the compliant dielectric element 12 from which the projections 204 project, and be omitted at locations at which the terminals 238 are formed. Further in such embodiment, the terminals 238 may be formed as portions of another conductive layer on the outer surfaces 36 of the contacts 38A, which are not covered by the solder resist layer 40, and extend from the outer surfaces 36, through and away from the solder resist layer 40.

Thus, in this embodiment, the terminals are the projections 238, which may be formed integrally with the contacts 38A or be portions of another conductive layer overlying the contacts 38A of the conductive layer 18, and the terminals 238 extend through the solder resist layer 40 and have exposed surfaces for electrical connection with an external microelectronic element. The terminals 238 may bend slightly due to the compliancy of the compliant dielectric element 12, to accommodate movement relative to the contacts 32B connected to the chip 102 that may be caused by differential thermal expansion and contraction.

In one embodiment, the terminals 238 constitute the entire thickness of the layer 18 and project beyond the outer surface 36 by a projection distance D_{P}. Merely by way of example, D_{P} may be about 50-300 μm. In the particular embodiment depicted, the terminals 238 have horizontal dimensions (in directions parallel to the surfaces of the dielectric layer) at a surface adjacent the compliant dielectric element 12 greater than the horizontal dimensions at a surface remote from the dielectric element 12, such that the horizontal dimensions of the terminal 238 decrease in the direction away from the element 12 so as to be in the form of a post, which desirably is a substantially rigid solid metal post.

In some embodiments of the assembly 200, one or more solder masses 42 may be formed on the exposed surfaces of the terminals 238.

In some embodiments, the terminals 238 may be adapted to simultaneously carry different electrical signals or electrical potentials, and be bonded to an external component 150 similarly as in FIG. 6.

In a further embodiment (FIG. 8), a microelectronic assembly 300 has features similar to that shown in FIG. 6. In this embodiment, fabrication is performed to provide that contacts 38A of the conductive portions 38 are aligned with the conductive vias 26 and the solder masses 42, thus omitting the traces 38B extending along the surface 16 of the compliant dielectric element 12, as in FIGS. 6 and 7. Also in this embodiment, the solder resist may be omitted, such that portions of the surface 16 of the element 12 not covered by the conductive portions 38, and portions of exposed surfaces of the conductive portions 38 not covered by the solder masses 42, may be exposed in the assembly 300.

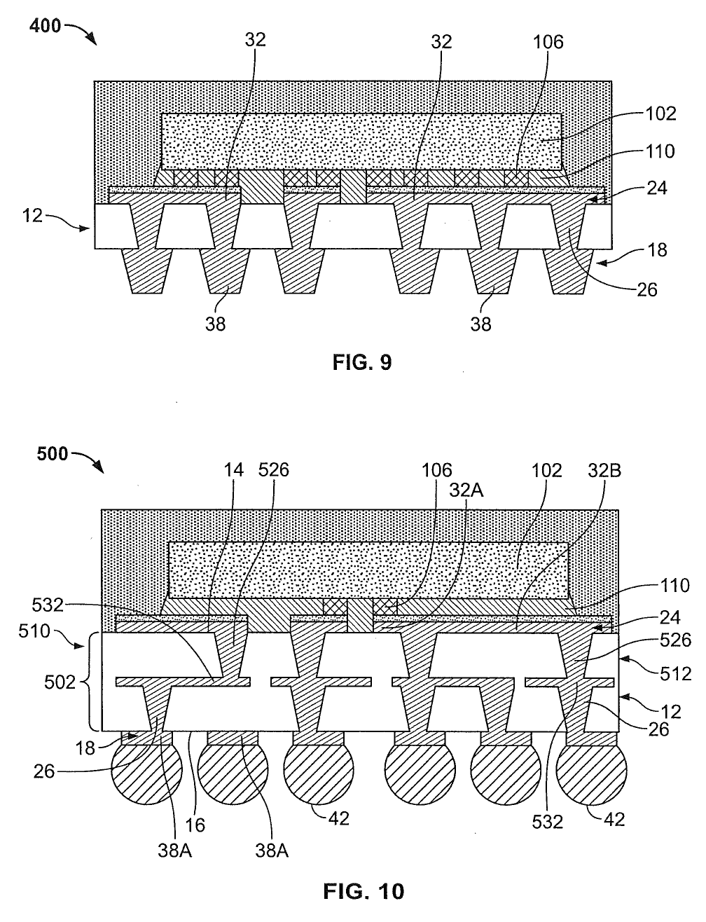

In a further embodiment (FIG. 9), a microelectronic assembly 400 has features similar to that shown in FIG. 8, except that the conductive portions 38 are shaped in the form of posts, the posts serving as terminals of the substrate to which an external chip may be connected. The conductive portions 38 are aligned with the conductive vias 26, which electrically connect the conductive portions 38 that serve as the terminals of the substrate with the conductive portions 32.

In a further embodiment (FIG. 10), a microelectronic assembly 500 has features similar to that shown in FIG. 8, except that the structure of a compliant dielectric element 502 can include compliant dielectric layers 12 and 512. In this case, substrate 510 of the assembly 500 can be similar to the substrate described above relative to FIG. 8, with the addition of conductive traces 532 disposed between the top surface 14 and bottom surface 16 of the compliant dielectric element 502 and extending in a lateral direction parallel to the surfaces 14 and 16. Additional conductive vias 526 may electrically connect the traces 532 with conductive portions, e.g., traces and contacts which extend along the surface 14 of the compliant dielectric element 502. Thus, as seen in FIG. 10, the contacts 38A of the assembly 500 at the surface 16 of the compliant dielectric element 502 serve as terminals which are electrically connected with the conductive portions 32 and contacts to the microelectronic element 102 through the conductive vias 26, the traces 532 and the conductive vias 526.

In a further embodiment (FIG. 11), a microelectronic assembly 600 has features similar to that shown in FIG. 10, except that the terminals are conductive portions 38 at the surface 16 of the compliant dielectric element 502 which are in the shape of posts, similarly as in the assembly 400 shown in FIG. 9.

In some embodiments, the assemblies of FIGS. 8-11 may include a solder resist layer overlying the surface 16 of the compliant dielectric element, such as described above with reference to FIGS. 6 and 7.

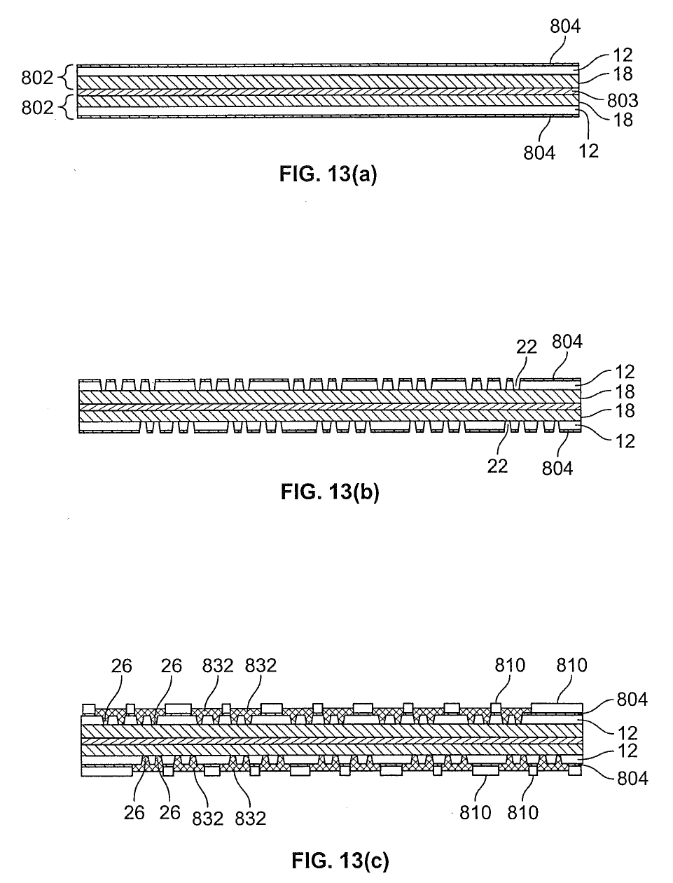

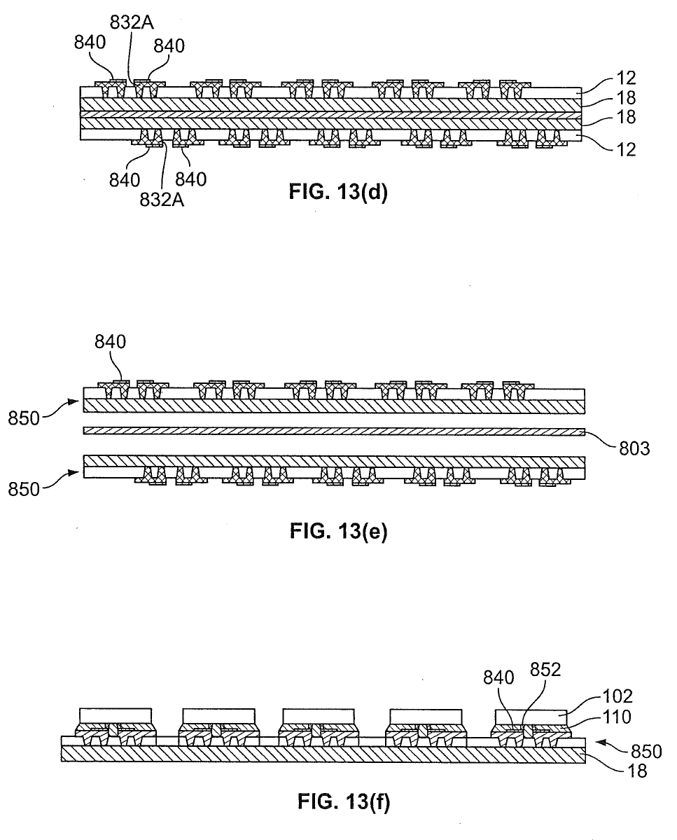

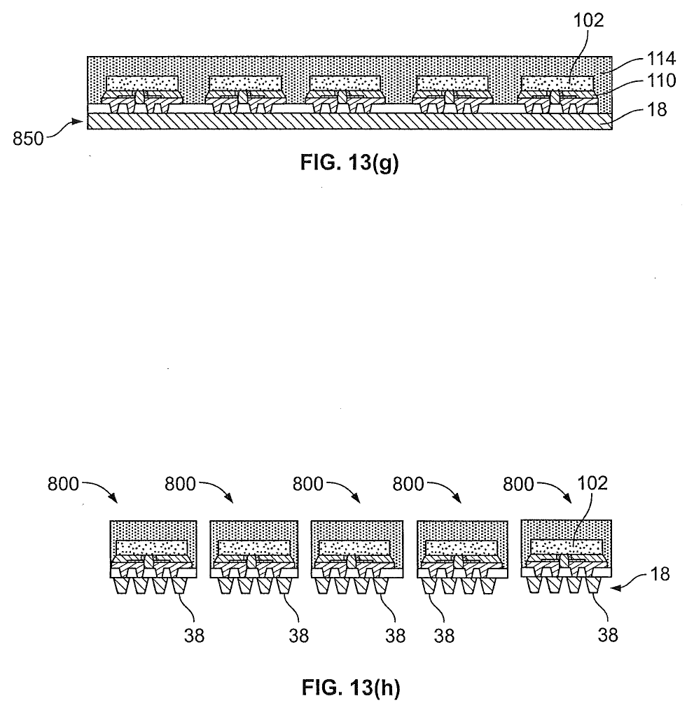

FIGS. 13(a)-13(h) illustrate a method of fabricating a microelectronic assembly 800, in accordance with another embodiment of the invention. Referring to FIG. 13(a), laminates 802 may be attached back-to-back by a peelable tape 803, where each of the laminates may include a compliant dielectric element laminated to a conductive structure 18, such as continuous layer of metal, which serves as a carrier of the element 12, and to a layer of conductive material 804 which is at a surface of the element 12 remote from the surface of the element 12 adjacent to the conductive layer 18. The layer 804 may include copper and, in one example, may have a thickness under 5 μm. Referring to FIG. 13(b), holes 22 may be formed in the compliant dielectric elements 12 by laser scribing. Referring to FIG. 13(c), a resist or solder mask 810 may be formed on portions of the conductive layers 804 by photolithography. Conductive material, such as copper, may be applied by a plating process to form the conductive vias 26 in the holes 22, and conductive portions 832. The conductive portions 832 contain conductive material of the layer 804 (not shown in FIG. 13(c)), and include contacts and traces extending along the surfaces 14 of the elements 12 from the contacts. The solder mask 810 may be removed, and then flash etching may be performed to remove portions of the layer 804 which had been covered by the removed solder mask 810, and portions of the top surface of the conductive portions 832. Referring to FIG. 13(d), conductive material portions or pads 840 may be formed over contacts 832A by electrolytic plating of conductive material, such as tin. The resulting substrates 850 may be separated from the peelable tape 803, as shown in FIG. 13(e). Referring to FIG. 13(f), the substrate 850 may be joined to microelectronic elements 102 by masses of a conductive material such as a bond metal, e.g., solder, tin or indium or a conductive paste 852, which electrically interconnects and bonds contacts (not shown) of the elements 102 with the pads 840, and an underfill 110 may be applied between each of the elements 102 and the substrate.

An encapsulant 114 may then be applied to cover portions of the substrate, the chips and underfill, such as by molding, as shown in FIG. 13(g). In a particular embodiment, the underfill 110 and the encapsulant 114 can be applied at the same time to the assembled structure of the microelectronic elements and the substrate and may be the same material.

In yet another variation, an underfill of the “no flow” type may be applied to the substrate 850 or to the microelectronic elements prior to joining the substrate with the microelectronic elements, and then such no flow underfill can be cured after the joining step. The encapsulant 114 then is a different material applied after the microelectronic elements 102 are assembled with the substrate 850.

Referring to FIG. 13(h), the substrate covered by the encapsulant may then be severed to obtain discrete microelectronic assemblies 800 each containing a microelectronic element 102, and the conductive layer 18 may be etched to form conductive portions 38, which serve as terminals, such as shown in FIG. 9, or alternatively pads, of each of the discrete microelectronic assemblies 800.

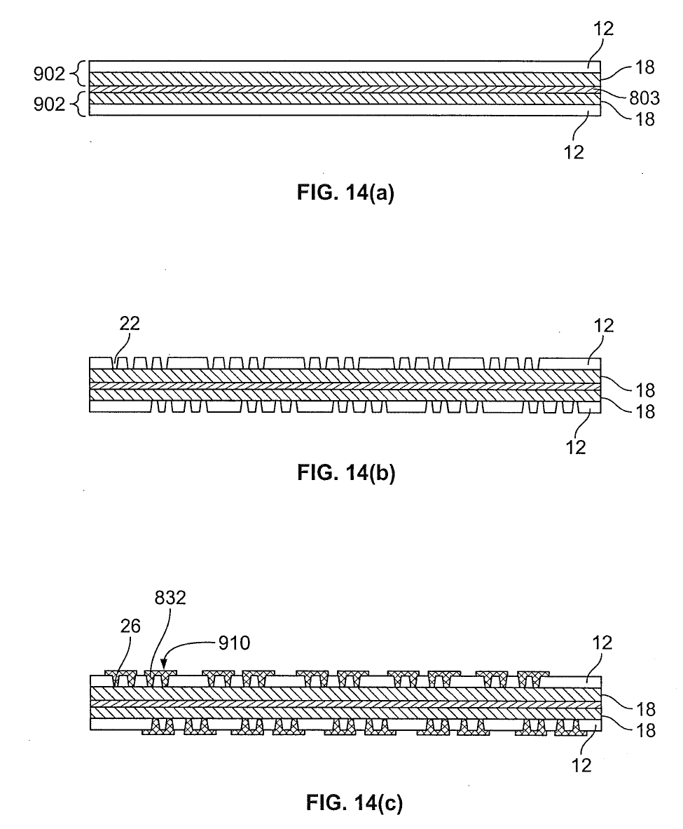

In a further embodiment, referring to FIGS. 14(a)-14(c), laminates 902 including a compliant dielectric element 12 laminated to a conductive layer 18 may be attached back-to-back, similarly as shown in FIG. 13, and holes 22 may be formed in the compliant dielectric elements 12 by laser scribing. A conductive paste 910 may then be printed selectively, using a stencil, into the holes 22 to form the conductive vias 26, and onto uncovered portions of the compliant dielectric element 12 to form the conductive portions 832. The processing may then be performed similarly as shown in FIGS. 13(d)-13(h), to obtain discrete microelectronic assemblies.

The microelectronic assemblies described above can be utilized in construction of diverse electronic systems, as shown in FIG. 12. For example, a system 700 in accordance with a further embodiment of the invention includes a microelectronic assembly 706 as described above in conjunction with other electronic components 708 and 710. In the example depicted, component 708 is a semiconductor chip whereas component 710 is a display screen, but any other components can be used. Of course, although only two additional components are depicted in FIG. 12 for clarity of illustration, the system may include any number of such components. The microelectronic assembly 706 may be any of the assemblies described above. In a further variant, any number of such microelectronic assemblies may be used. Microelectronic assembly 706 and components 708 and 710 are mounted in a common housing 711, schematically depicted in broken lines, and are electrically interconnected with one another as necessary to form the desired circuit. In the exemplary system shown, the system includes a circuit panel 712 such as a flexible printed circuit board, and the circuit panel includes numerous conductors 714, of which only one is depicted in FIG. 12, interconnecting the components with one another. However, this is merely exemplary; any suitable structure for making electrical connections can be used. The housing 711 is depicted as a portable housing of the type usable, for example, in a cellular telephone or personal digital assistant, and screen 710 is exposed at the surface of the housing. Where structure 706 includes a light sensitive element such as an imaging chip, a lens 716 or other optical device also may be provided for routing light to the structure. Again, the simplified system shown in FIG. 12 is merely exemplary; other systems, including systems commonly regarded as fixed structures, such as desktop computers, routers and the like can be made using the structures discussed above.

Although the invention herein has been described with reference to particular embodiments, it is to be understood that these embodiments are merely illustrative of the principles and applications of the present invention.

What is claimed is:

1. A microelectronic assembly comprising:
a microelectronic element having a plurality of element contacts at a face thereof;
a compliant dielectric element having a Young's modulus of less than about two gigapascal (GPa), the compliant dielectric element having a first surface facing the face of the microelectronic element, a second surface opposed thereto, a plurality of substrate contacts at the first surface joined to the element contacts, first traces extending along the first surface away from the substrate contacts, a plurality of terminals at the second surface, and a plurality of first conductive vias, wherein the substrate contacts are electrically connected with the terminals through the first conductive vias; and
a rigid underfill between the face of the microelectronic element and the first surface of the compliant dielectric element,
wherein the terminals are usable for bonding the microelectronic assembly to corresponding contacts of a component external to the microelectronic assembly.

2. The microelectronic assembly of claim 1, wherein at least one of the first conductive vias extends from at least one of the first traces.

3. The microelectronic assembly of claim 1 further comprising:
solder masses joined to the terminals.

4. The microelectronic assembly of claim 1, wherein at least one of the terminals is a substantially rigid solid metal post.

5. The microelectronic assembly of claim 4 further comprising:
solder joined to the at least one metal post.

6. The microelectronic assembly of claim 1, wherein the terminals include first and second substantially rigid solid metal posts adapted to simultaneously carry respective first and second electrical signal potentials, the first and second potentials being different.

7. The microelectronic assembly of claim 1, wherein the terminals are portions of a conductive layer including the terminals and second traces extending along the second surface away from the terminals.

8. The microelectronic assembly of claim 7 further comprising:
a solder resist layer overlying the second surface of the compliant dielectric element, wherein the solder resist layer overlies at least some of the second traces.

9. The microelectronic assembly of claim 1 further comprising:
a solder resist layer overlying the second surface of the compliant dielectric element.

10. The microelectronic assembly of claim 1 further comprising:
bonding material between the terminals and the external component joining the terminals to the external component.

11. The microelectronic assembly of claim 10, wherein the bonding material is solder and the external component is a circuit panel.

12. The microelectronic assembly of claim 1 further comprising:
second conductive traces disposed between the first and second surfaces and extending in a lateral direction parallel to the first and second surfaces, and second conductive vias extending between the first and second traces, wherein the terminals are electrically connected with the second conductive traces through the first conductive vias.

13. The microelectronic assembly of claim 12, wherein the compliant dielectric element includes first and second compliant dielectric layers, wherein the second conductive traces extend along a boundary between the first and second compliant dielectric layers, the first conductive vias extending through the first compliant dielectric layer and the second conductive vias extending through the second compliant dielectric layer.

14. The microelectronic assembly of claim 12, wherein the first and second conductive vias extend from the second traces.

15. The microelectronic assembly of claim 12 further comprising:
solder masses joined to the terminals.

16. The microelectronic assembly of claim 12, wherein at least one of the terminals is a substantially rigid solid metal post.

17. The microelectronic assembly of claim 16 further comprising:
solder joined to the at least one metal post.

18. The microelectronic assembly of claim 12, wherein the terminals include first and second substantially rigid solid metal posts adapted to simultaneously carry respective first and second electrical signal potentials, the first and second potentials being different.

19. The microelectronic assembly of claim 12, wherein the terminals are portions of a conductive layer including the terminals and third traces extending along the second surface away from the terminals.

20. The microelectronic assembly of claim 19 further comprising:
a solder resist layer overlying the second surface, wherein the solder resist layer overlies at least some of the third traces.

21. The microelectronic assembly of claim 12 further comprising:
a solder resist layer overlying the second surface.

22. The microelectronic assembly of claim 12 further comprising:
bonding material between the terminals and the external component joining the terminals to the external component.

23. The microelectronic assembly of claim 22, wherein the bonding material is solder and the external component is a circuit panel.

24. A microelectronic assembly comprising:
a microelectronic element having a plurality of element contacts at a face thereof;
a compliant dielectric element having a Young's modulus of less than about two gigapascal (GPa), the compliant dielectric element having a first surface facing the face of the microelectronic element, a second surface opposed thereto, a plurality of substrate contacts at the first surface joined to the element contacts, traces extending along the first surface away from the substrate contacts, a plurality of terminals at the second surface, and a plurality of conductive vias, wherein the substrate contacts are electrically connected with the terminals through the conductive vias; and
a rigid underfill between the face of the microelectronic element and the first surface of the compliant dielectric element,
wherein the terminals are electrically connected with the conductive vias and usable for bonding the microelectronic assembly to corresponding contacts of a component external to the microelectronic assembly such that the terminals are movable with respect to the substrate contacts.

25. The microelectronic assembly of claims 1, 12 and 24, wherein the microelectronic element is a chip having conductive bumps as the element contacts.

26. The microelectronic assembly of claim 24, wherein the terminals are portions of a conductive layer including the terminals and second traces extending along the second surface away from the terminals.

27. The microelectronic assembly of claim 26 further comprising:
a solder resist layer overlying the second surface of the compliant dielectric element, wherein the solder resist layer overlies at least some of the second traces.

28. The microelectronic assembly of claim 24 further comprising:
a solder resist layer overlying the second surface of the compliant dielectric element.

29. A system comprising an assembly according to claims 1, 12 or 24 and one or more other electronic components electrically connected to the assembly.

30. The system of claim 29, wherein the terminals are electrically connected to a circuit panel.

31. The system as claimed in claim 29, further comprising a housing, the assembly and the other electronic components being mounted to the housing.

32. A method of fabricating a microelectronic assembly comprising:
joining element contacts at a face of a microelectronic element with a plurality of substrate contacts at a first surface of a compliant dielectric element, the compliant dielectric element having a Young's modulus of less than about two gigapascal (GPa) and a second surface opposed to the first surface, traces extending along the first surface away from the substrate contacts, a conductive structure at the second surface and a plurality of conductive vias;
forming a rigid underfill between the face of the microelectronic element and the first surface of the compliant dielectric element; and
patterning the conductive structure after the joining step to form terminals at the second surface of the compliant dielectric element, wherein the substrate contacts are electrically connected with the terminals through the conductive vias, the terminals usable to electrically connect the microelectronic assembly to a component external to the microelectronic assembly.

33. The method of claim 32 further comprising:
bonding the terminals to corresponding contacts of a component external to the microelectronic assembly.

34. The method of claim 33, wherein the external component is a circuit panel.

35. The method of claim 33, wherein the bonding includes applying solder to join the terminals to the contacts of the external component.

36. The method of claim 32, wherein the conductive structure includes a continuous layer of metal and the patterning step includes etching the continuous layer to form the terminals.

37. The method of claim 36, wherein the patterning step is performed subsequent to the forming the rigid underfill between the face of the microelectronic element and the first surface of the compliant dielectric element.

38. The method of claim 32, wherein the element contacts are electrically connected with the substrate contacts through a conductive paste.

39. The method of claim 32, wherein the substrate contacts, the traces and the conductive vias are formed from a conductive paste.
